(19) United States
(12) Patent Application Publication
(10) Pub. No.: US 2026/0271214 A1
(43) Pub. Date: Sep. 10, 2026

(54) RACK AND SLIDING RAIL ASSEMBLY

(71) Applicants: INVENTEC (PUDONG) TECHNOLOGY CORPORATION, Shanghai (CN); INVENTEC CORPORATION, Taipei City (TW)

(72) Inventors: Kai CHUANG, Taipei City (TW); Ming Tsung LIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/313,582

(22) Filed: Aug. 28, 2025

(30) Foreign Application Priority Data
Mar. 10, 2025 (CN) 202510273355.6

(51) Int. Cl. H05K 7/14

(52) U.S. Cl. CPC H05K 7/1489

(57) ABSTRACT

A rack configured to accommodate at least one server, and includes a rack body and at least one sliding rail assembly. The rack body includes at least one assembling portion. The at least one sliding rail assembly includes an assembling frame and a sliding rail. The assembling frame is detachably disposed on the at least one assembling portion. The assembling frame is located between the at least one assembling portion and the sliding rail. The sliding rail includes a rail component and a slider. The rail component is disposed on the assembling frame. The slider is slidably disposed on the rail component. The slider is configured for the at least one server to be detachably disposed thereon.

### CROSS-REFERENCE TO RELATED APPLICATIONS

This non-provisional application claims priority under 35 U.S.C. § 119(a) on Patent Application No(s). 202510273355.6 filed in China, on Mar. 10th, 2025, the entire contents of which are hereby incorporated by reference.

### BACKGROUND OF THE INVENTION

### Technical Field of the Invention

The invention relates to a rack, more particularly to a rack including a sliding rail assembly.

### Description of the Related Art

Nowadays, the information technology is under rapid development and personal computers are indispensable for corporations and individuals when handling various tasks. As communication technology becomes highly developed, the regional business transaction being replaced by transnational electronic commerce has become a trend, and the transnational electronic commerce involves massive data computation that typical personal computers are unable to deal with. Therefore, the data center employs various forms of server systems, such as rack server system, blade server system, and tower server system, to provide e-commerce services for users.

For example, the rack server meeting the open compute project (OCP) will be described below. Generally, servers are assembled in a rack via angle iron brackets or slide rails. The conventional angle iron brackets are fixed to the rack, and cannot be moved relative to the rack, thereby reducing the assembling flexibility of the servers. In addition, when a maintenance of the servers is required, in order to allow the servers to be supported by the angle iron brackets, the servers cannot be fully pulled out of the rack, which causes inconvenience of the maintenance of the servers. On the other hand, if the slide rails are adopted to be assembled in the rack, the conventional slide rails are difficult to be matched and assembled into the rack meeting the OCP due to the structure thereof. Therefore, improving the convenience of assembly and maintenance of the servers and the rack is one of the key issues that researchers need to address.

### SUMMARY OF THE INVENTION

The invention provides a rack and a sliding rail assembly so as to improve the convenience of assembly and maintenance of servers and a rack.

One embodiment of the invention provides a rack configured to accommodate at least one server. The rack includes a rack body and at least one sliding rail assembly. The rack body includes at least one assembling portion. The at least one sliding rail assembly includes an assembling frame and a sliding rail. The assembling frame is detachably disposed on the at least one assembling portion. The assembling frame is located between the at least one assembling portion and the sliding rail. The sliding rail includes a rail component and a slider. The rail component is disposed on the assembling frame. The slider is slidably disposed on the rail component. The slider is configured for the at least one server to be detachably disposed thereon.

Another embodiment of the invention provides a sliding rail assembly configured to be disposed in a rack body of a rack and configured for at least one server to be detachably disposed thereon. The sliding rail assembly includes an assembling frame and a sliding rail. The assembling frame is configured to be detachably disposed on the at least one assembling portion of the rack body. The assembling frame is configured to be located between the at least one assembling portion and the sliding rail. The sliding rail includes a rail component and a slider. The rail component is disposed on the assembling frame. The slider is slidably disposed on the rail component. The slider is configured for the at least one server to be detachably disposed thereon.

According to the rack and the sliding rail assembly disclosed in the above embodiment, the rack includes the sliding rail assemblies. Therefore, when a maintenance of the server is required, the server can be fully pulled out of the rack body via the sliders, while being supported by the sliding rail assemblies. Accordingly, the convenience of assembling the server can be improved.

In addition, the sliding rail assemblies disposed in the rack body not only allows the server to be smoothly slid in the rack body to reduce friction generated between the server and the rack body, but also prevents the server 40 from being damaged by reducing the vibration generated during the slide of the server. Moreover, the server can be assembled in the rack body more firmly via the assembly of the assembling frames and the sliders.

In addition, the assembling frames of the sliding rail assemblies are detachably disposed on the rack body, and the server is detachably disposed on the sliders. Therefore, the flexibility and the convenience of assembling the server into the rack body can be improved.

Moreover, compared with a conventional sliding rails which are difficult to be matched and assembled into the rack meeting the OCP due to the structure thereof (e.g. the assembling direction), the assembling frames of this embodiment are respectively located between the assembling portions and the sliding rails, such that the sliding rail assemblies can be matched and assembled into the rack body meeting the OCP. Accordingly, the convenience of assembling the server into the rack body can be further improved.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view of a rack in accordance with an embodiment of the invention;

FIG. 2 is an exploded view of the rack in FIG. 1;

FIG. 3 is an enlarged perspective view of the rack in FIG. 2;

FIG. 4 is a perspective view of one of sliding rail assemblies of the rack in FIG. 1;

FIG. 5 is an enlarged cross-sectional view of the rack in FIG. 1;

FIG. 6 is an enlarged cross-sectional view of the rack in FIG. 1 showing that an assembling frame has not been assembled into a rack body yet;

FIG. 7 is an enlarged cross-sectional view of the rack in FIG. 1 showing that the assembling frame is assembled into the rack body;

FIG. 8 is a cross-sectional view of the rack in FIG. 1 showing that a server has not been assembled on sliding rails yet;

FIG. 9 is a perspective view of the rack in FIG. 1 showing that the server is assembled on the sliding rails;

FIG. 10 is a side view of the rack in FIG. 1 showing that a second positioning structure is located at a wide portion;

FIG. 11 is a side view of the rack in FIG. 1 showing that the second positioning structure is located at a narrow portion; and

FIG. 12 is a perspective view of the rack in FIG. 1 showing that the server is assembled into the rack body.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

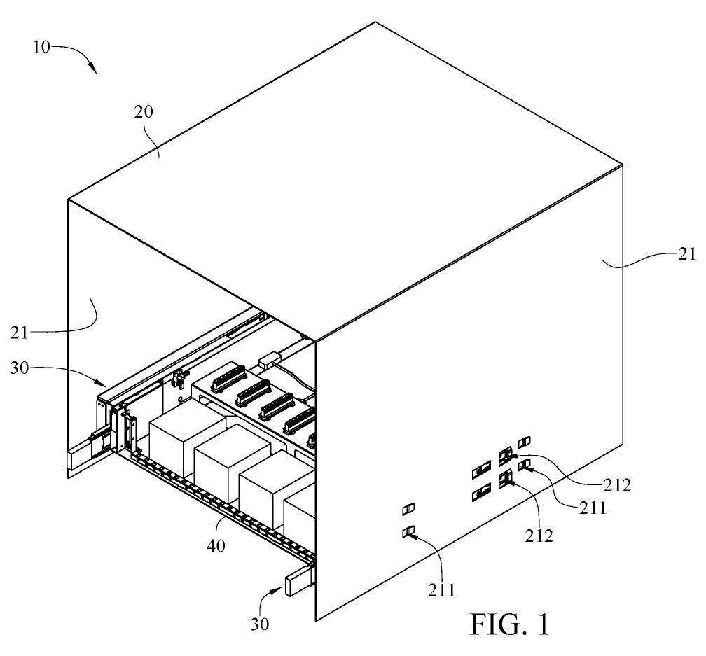

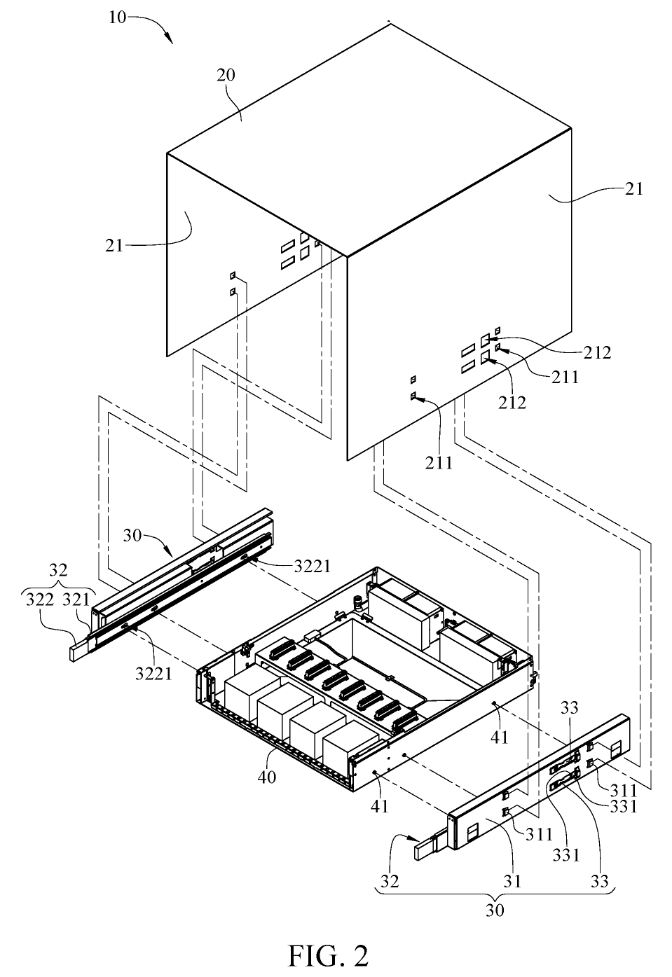

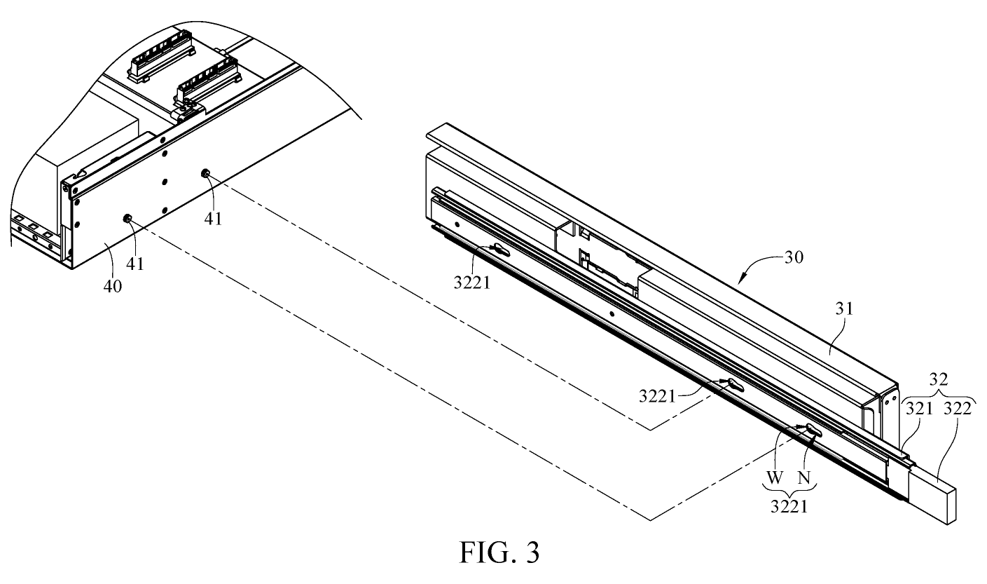

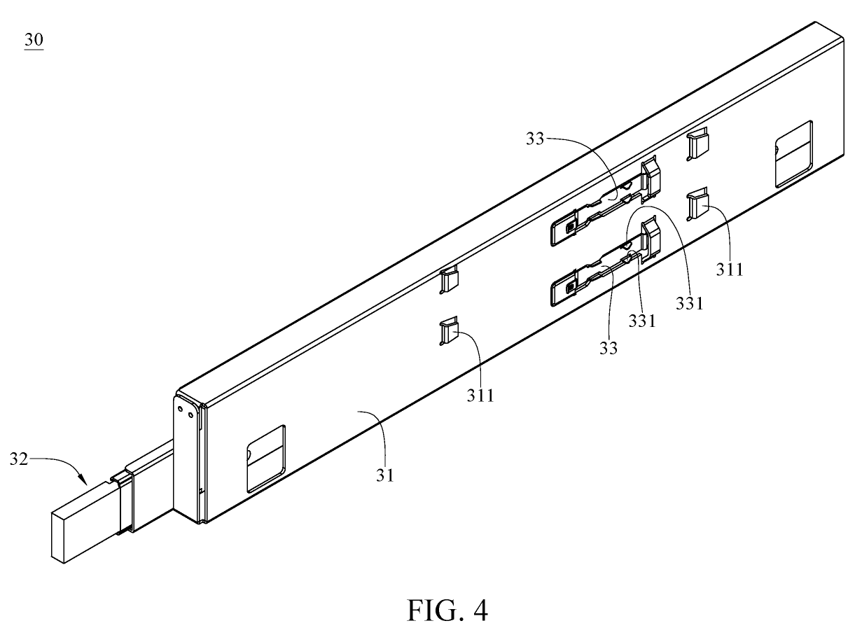

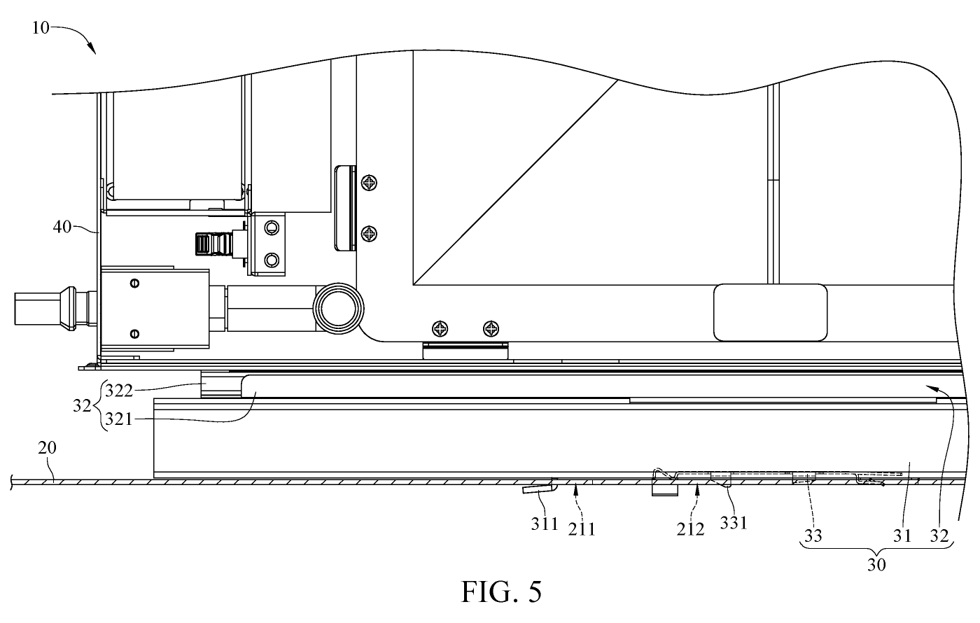

Please refer to FIGS. 1 to 5, where FIG. 1 is a perspective view of a rack 10 in accordance with an embodiment of the invention, FIG. 2 is an exploded view of the rack 10 in FIG. 1, FIG. 3 is an enlarged perspective view of the rack 10 in FIG. 2, FIG. 4 is a perspective view of one of sliding rail assemblies 30 of the rack 10 in FIGS. 1, and 5 is an enlarged cross-sectional view of the rack 10 in FIG. 1.

In this embodiment, the rack 10 meeting, for example, the OCP, and is configured to support a server 40. The rack 10 includes a rack body 20 and two sliding rail assemblies 30. The rack body 20 includes two assembling portions 21. An assembling space within the rack body 20, configured to accommodate the server 40, has a size of, for example, 24 inches. The two sliding rail assemblies 30 are detachably disposed on the two assembling portions 21, respectively. Since the two sliding rail assemblies 30 are respectively disposed on the two assembling portions 21 in similar manners, structures of the two sliding rail assemblies 30 are the same, and structures of the two assembling portions 21 are the same, only one sliding rail assembly 30 and only one assembling portion 21 will be described below.

Each of the sliding rail assemblies 30 includes an assembling frame 31 and a sliding rail 32. The assembling frame 31 is detachably disposed on the assembling portion 21. In detail, the assembling frame 31 includes a plurality of first engaging structures 311. The first engaging structures 311 are, for example, engaging protrusions. Each of the assembling portions 21 includes a plurality of second engaging structures 211. The second engaging structures 211 are, for example, engaging recesses. The assembling frame 31 is configured to be held in position on the rack body 20 via the first engaging structures 311 respectively engaged with the second engaging structures 211.

The assembling frame 31 is located between the assembling portion 21 and the sliding rail 32. The sliding rail 32 includes a rail component 321 and a slider 322. The rail component 321 is disposed on the assembling frame 31. For example, the rail component 321 is riveted to the assembling frame 31 to strengthen the assembly between the rail component 321 and the assembling frame 31. The slider 322 is slidably disposed on the rail component 321.

The slider 322 is configured for the server 40 to be detachably disposed thereon. In detail, the slider 322 includes a plurality of first positioning structures 3221. For example, the first positioning structures 3221 are pear-shaped positioning recesses. In detail, each of the first positioning structures 3221 includes a wide portion W and a narrow portion N. The wide portion W is connected to the narrow portion N, and a width of the wide portion W is greater than a width of the narrow portion N.

The server 40 includes a plurality of second positioning structures 41. The second positioning structures 41 are, for example, positioning protrusions. The first positioning structures 3221 are configured for the second positioning structures 41 to be slidably disposed therein, such that the second positioning structures 41 are located at the wide portions W or the narrow portions N, respectively. The server 40 is configured to be released from the slider 322 when the second positioning structures 41 are respectively disposed at the wide portions W, and is configured to be held in position on the slider 322 when the second positioning structures 41 are respectively disposed at the narrow portions N. The server 40 has a size of, for example, 19 inches. The server 40 having the size of 19 inches can be assembled into the rack body 20 having the assembling space in the size of 24 inches via the sliding rail assemblies 30.

In this embodiment, each of the sliding rail assemblies 30 may include a plurality of flexible components 33. The flexible components 33 are, for example, cantilevers which is elastic. The flexible components 33 are disposed on the assembling frame 31, and each of the flexible components 33 includes a plurality of first blocking structures 331. The first blocking structures 331 are, for example, blocking protrusions. Each of the assembling portions 21 may include a plurality of second blocking structures 212. The second blocking structures 212 are, for example, blocking recesses. The assembling frame 31 is configured to be further held in position on the rack body 20 via the first blocking structures 311 respectively blocking the second blocking structures 212.

In this embodiment, the rack 10 includes the sliding rail assemblies 30. Therefore, when a maintenance of the server 40 is required, the server 40 can be fully pulled out of the rack body 20 via the sliders 322, while being supported by the sliding rail assemblies 30. Accordingly, the convenience of assembling the server 40 can be improved.

In addition, the sliding rail assemblies 30 disposed in the rack body 20 not only allows the server 40 to be smoothly slid in the rack body 20 to reduce friction generated between the server 40 and the rack body 20, but also prevents the server 40 from being damaged by reducing the vibration generated during the slide of the server 40. Moreover, the server 40 can be assembled in the rack body 20 more firmly via the assembly of the assembling frames 31 and the sliders 322.

In addition, the assembling frames 31 of the sliding rail assemblies 30 are detachably disposed on the rack body 20, and the server 40 is detachably disposed on the sliders 322. Therefore, the flexibility and the convenience of assembling the server 40 into the rack body 20 can be improved.

Moreover, compared with a conventional sliding rails which are difficult to be matched and assembled into the rack meeting the OCP due to the structure thereof (e.g. the assembling direction), the assembling frames 31 of this embodiment are respectively located between the assembling portions 21 and the sliding rails 32, such that the sliding rail assemblies 30 can be matched and assembled into the rack body 20 meeting the OCP. Accordingly, the convenience of assembling the server 40 into the rack body 20 can be further improved.

In this embodiment, there are two assembling portions 21 and two sliding rail assemblies 30, and there is one server 40, but the invention is not limited thereto. In other embodiments, there may be one or more than two assembling portion(s) and one or more than two sliding rail assembly(s), and there may be multiple servers.

In this embodiment, there are multiple first engaging structures 311 and multiple second engaging structures 211, but the invention is not limited thereto. In other embodiments, there may be one first engaging structure and one second engaging structure.

In this embodiment, the first engaging structures 311 are engaging protrusions, and the second engaging structures 211 are engaging recesses, but the invention is not limited thereto. In other embodiments, the protrusion and recess configurations of the first engaging structures and the second engaging structures may be exchanged. That is, the first engaging structures may be engaging recesses, and the second engaging structures may be engaging protrusions.

In this embodiment, there are multiple first positioning structures 3221 and multiple second positioning structures 41, but the invention is not limited thereto. In other embodiments, there may be one first positioning structure and one second positioning structure.

In this embodiment, the first positioning structures 3221 are positioning recesses, and the second engaging structures 41 are positioning protrusions, but the invention is not limited thereto. In other embodiments, the recess and protrusion configurations of the first positioning structures and the second positioning structures may be exchanged. That is, the first positioning structures may be positioning protrusions, and the second positioning structures may be positioning recesses.

In this embodiment, there are multiple flexible components 33, but the invention is not limited thereto. In other embodiments, there may be one flexible component.

In this embodiment, there are multiple first blocking structures 331 and multiple second blocking structures 212, but the invention is not limited thereto. In other embodiments, there may be one first blocking structure and one second blocking structure.

In this embodiment, the first blocking structures 331 are blocking protrusions, and the second blocking structures 212 are blocking recesses, but the invention is not limited thereto. In other embodiments, the protrusion and recess configurations of the first blocking structures and the second blocking structures may be exchanged. That is, the first blocking structures may be blocking recesses, and the second blocking structures may be blocking protrusions.

In this embodiment, the rail component 321 is riveted to the assembling frame 31 but the invention is not limited thereto. In other embodiments, the rail component may be disposed on the assembling frame via other fixing manners.

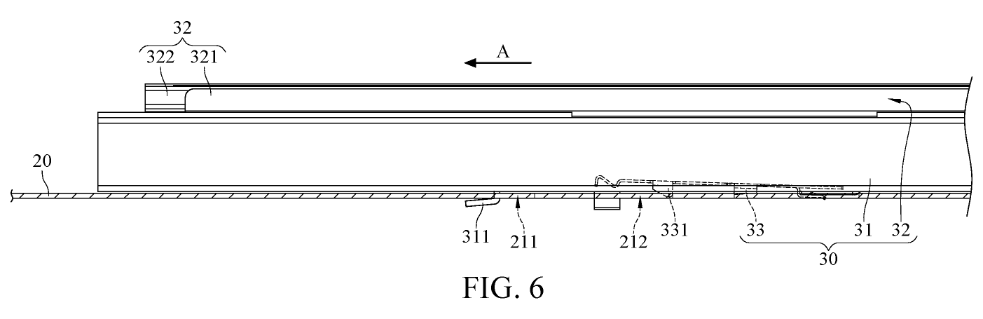

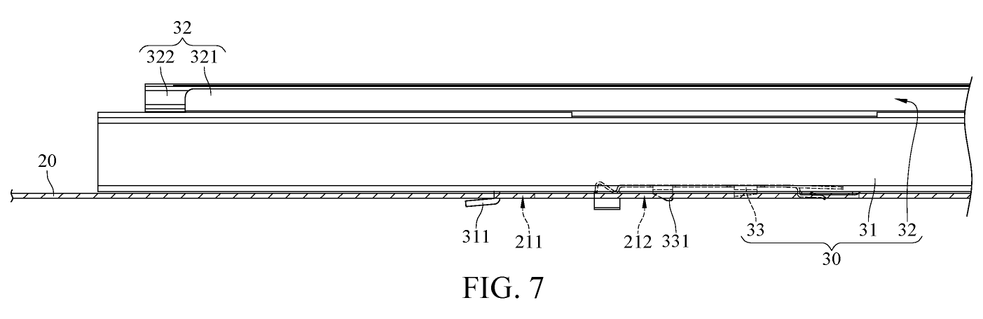

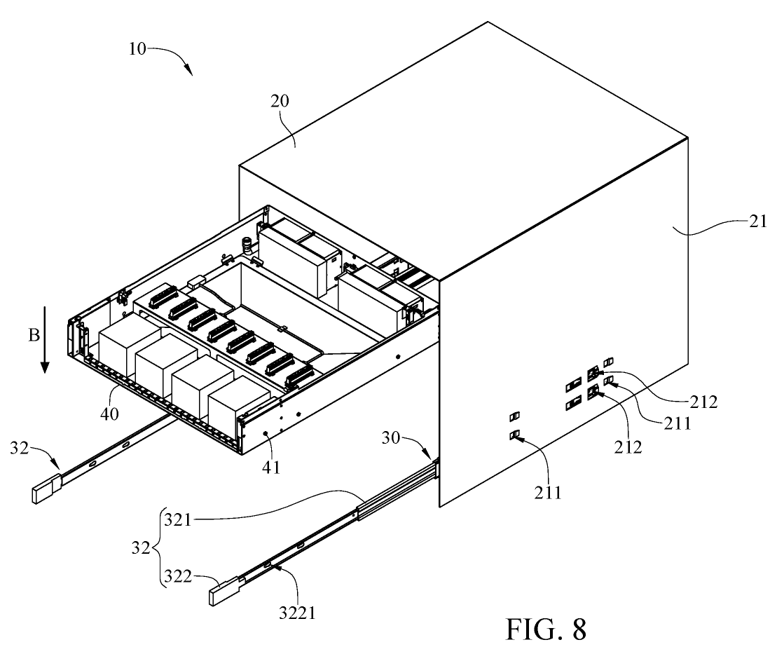

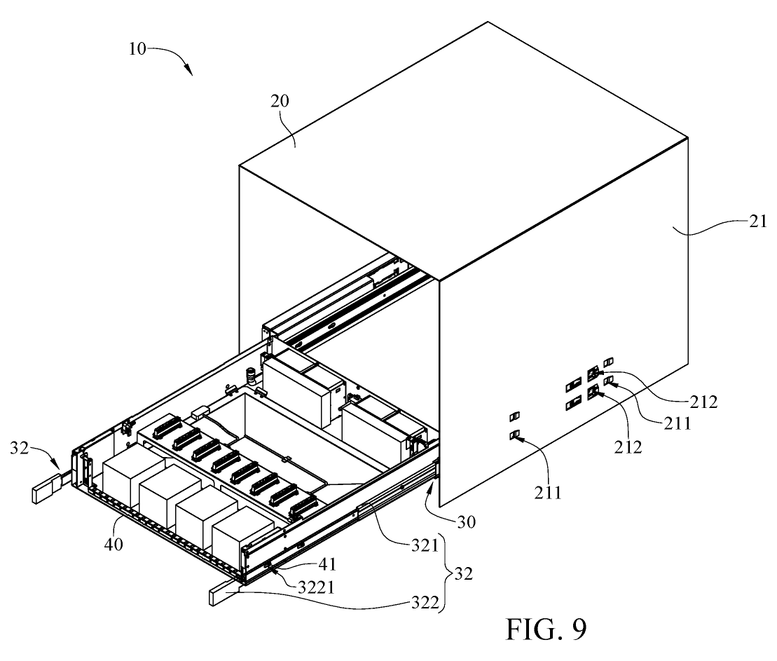

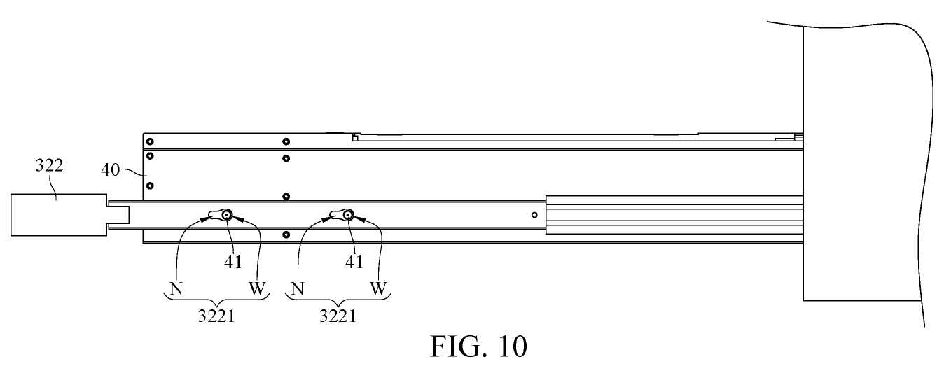

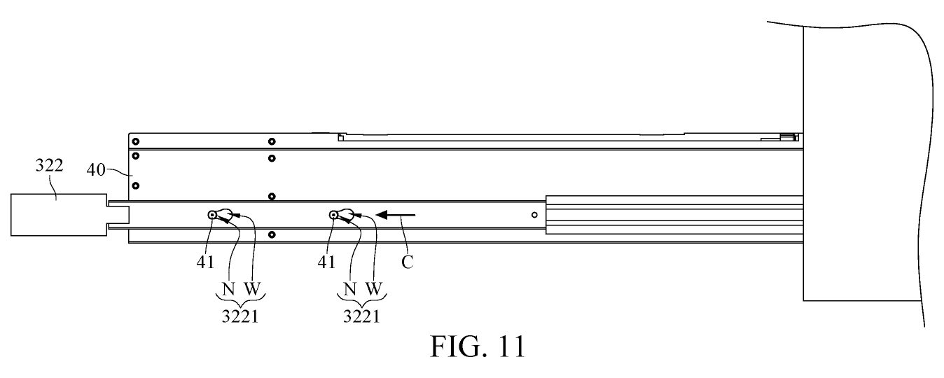

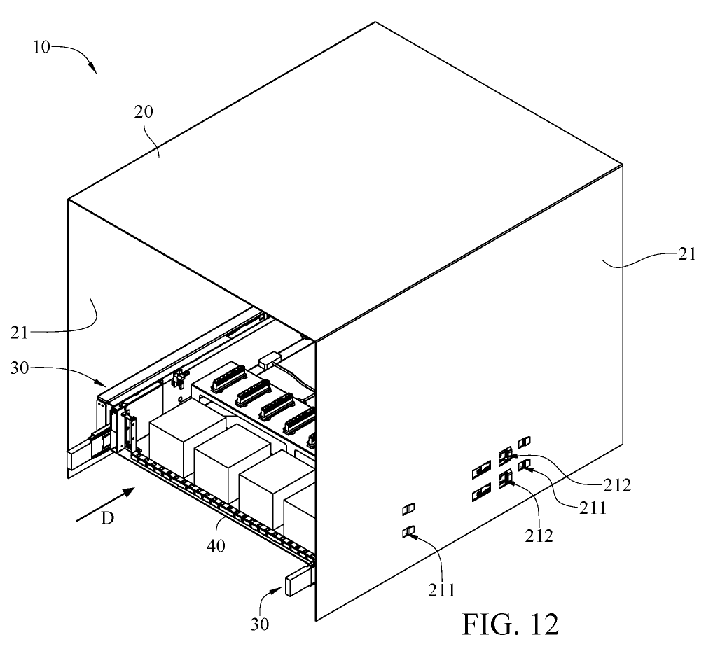

Please refer to FIGS. 6 to 12, where FIG. 6 is an enlarged cross-sectional view of the rack 10 in FIG. 1 showing that the assembling frame 31 has not assembled into the rack body 20 yet, FIG. 7 is an enlarged cross-sectional view of the rack 10 in FIG. 1 showing that the assembling frame 31 is assembled into the rack body 20, FIG. 8 is a cross-sectional view of the rack 10 in FIG. 1 showing that the server 40 has not assembled on the sliding rails 32 yet, FIG. 9 is a perspective view of the rack 10 in FIG. 1 showing that the server 40 is assembled on the sliding rails 32, FIG. 10 is a side view of the rack 10 in FIG. 1 showing that the second positioning structure 41 is located at the wide portion W, FIG. 11 is a side view of the rack 10 in FIG. 1 showing that the second positioning structure 41 is located at the narrow portion N, and FIG. 12 is a perspective view of the rack 10 in FIG. 1 showing that the server 40 is assembled into the rack body 20.

In this embodiment, when the server 40 is required to be assembled into the rack body 20, firstly, as shown in FIGS. 6 and 7, the assembling frames 31 of the sliding rail assemblies 30 are assembled on the assembling portions 21 of the rack body 20 along a direction A, respectively. During the assembling process, the first engaging structures 311 of the assembling frames 31 are respectively engaged with the second engaging structures 211 of the assembling portions 21, and the first blocking structures 331 respectively block the second blocking structures 212 of the assembling portions 21 by moving the flexible components 33 and thus releasing elastic potential energy thereof. Accordingly, the assembling frames 31 can be held in position on the rack body 20.

Then, as shown in FIGS. 8 and 9, the server 40 is assembled on the sliders 322 of the sliding rail assemblies 30 along a direction B. In detail, as shown in FIGS. 10 and 11, when the server is placed on the sliders 322, the second positioning structures 41 of the server 40 are located at the wide portions W of the first positioning structures 3221, respectively. Then, the server 40 is moved along a direction C, such that the second positioning structures 41 can be moved from the wide portions W to the narrow portions N. Accordingly, the server 40 can be held in position on the sliders 322. Then, as shown in FIG. 12, the server 40 is moved into the rack body 20 along a direction D via the sliders 322, and the assembly of the server 40 and the rack body 20 can be completed.

On the contrary, when the server 40 is required to be removed from the rack body 20, firstly, the server 40 is moved out of the rack body 20 along a direction opposite to the direction D via the sliders 322. Then, the server 40 is moved along a direction opposite to the direction C, such that the second positioning structures 41 can be moved from the narrow portions N to the wide portions W. Accordingly, the server 40 can be released from the sliders 322, and the server 40 can be detached from the sliders 322 along a direction opposite to the direction B. Therefore, the server 40 can be removed from the rack body 20.

When the sliding rail assemblies 30 are required to be removed from the rack body 20, the first engaging structures 311 are respectively disengaged from the second engaging structures 211, and the first blocking structures 331 are respectively released from the second blocking structures 212 by moving the flexible components 33. Accordingly, the sliding rail assemblies 30 can be removed from the rack body 20.

According to the rack and the sliding rail assembly disclosed in the above embodiment, the rack includes the sliding rail assemblies. Therefore, when a maintenance of the server is required, the server can be fully pulled out of the rack body via the sliders, while being supported by the sliding rail assemblies. Accordingly, the convenience of assembling the server can be improved.

In addition, the sliding rail assemblies disposed in the rack body not only allows the server to be smoothly slid in the rack body to reduce friction generated between the server and the rack body, but also prevents the server from being damaged by reducing the vibration generated during the slide of the server. Moreover, the server can be assembled in the rack body more firmly via the assembly of the assembling frames and the sliders.

In addition, the assembling frames of the sliding rail assemblies are detachably disposed on the rack body, and the server is detachably disposed on the sliders. Therefore, the flexibility and the convenience of assembling the server into the rack body can be improved.

Moreover, compared with a conventional sliding rails which are difficult to be matched and assembled into the rack meeting the OCP due to the structure thereof (e.g. the assembling direction), the assembling frames of this embodiment are respectively located between the assembling portions and the sliding rails, such that the sliding rail assemblies can be matched and assembled into the rack body meeting the OCP. Accordingly, the convenience of assembling the server into the rack body can be further improved.

In this embodiment, the rack and the sliding rail assembly of the invention can be applied to a server. The server can apply artificial intelligence (AI) computing, edge computing, and can also be used as a 5G server, a cloud server or a Vehicle-to-everything server.

It will be apparent to those skilled in the art that various modifications and variations can be made to the invention. It is intended that the specification and examples be considered as exemplary embodiments only, with the scope of the invention being indicated by the following claims.

What is claimed is:

1. A rack, configured to accommodate at least one server, and the rack comprising:
a rack body, comprising at least one assembling portion; and
at least one sliding rail assembly, comprising:
an assembling frame, detachably disposed on the at least one assembling portion; and
a sliding rail, wherein the assembling frame is located between the at least one assembling portion and the sliding rail, the sliding rail comprises a rail component and a slider, the rail component is disposed on the assembling frame, the slider is slidably disposed on the rail component, and the slider is configured for the at least one server to be detachably disposed thereon.

2. The rack according to claim 1, wherein the slider comprises at least one first positioning structure, the at least one first positioning structure comprises a wide portion and a narrow portion, the wide portion is connected to the narrow portion, a width of the wide portion is greater than a width of the narrow portion, the at least one first positioning structure is configured for at least one second positioning structure of the at least one server to be slidably disposed therein and located at the wide portion or the narrow portion, the at least one server is configured to be released from the sliding rail when the at least one second positioning structure is disposed at the wide portion, and the at least one server is configured to be held in position on the sliding rail when the at least one second positioning structure is disposed at the narrow portion.

3. The rack according to claim 1, wherein the assembling frame comprises at least one first engaging structure, the at least one assembling portion of the rack body comprises at least one second engaging structure, and the assembling frame is configured to be held in position on the rack body via the at least one first engaging structure engaged with the at least one second engaging structure.

4. The rack according to claim 1, wherein the at least one sliding rail assembly further comprises at least one flexible component, the at least one flexible component is disposed on the assembling frame, the at least one flexible component comprises at least one first blocking structure, the at least one assembling portion of the rack body comprises at least one second blocking structure, and the assembling frame is configured to be held in position on the rack body via the at least one first blocking structure blocking the at least one second blocking structure.

5. The rack according to claim 1, wherein the rail component is riveted to the assembling frame.

6. A sliding rail assembly, configured to be disposed in a rack body of a rack and configured for at least one server to be detachably disposed thereon, and the sliding rail assembly comprising:
an assembling frame, configured to be detachably disposed on the at least one assembling portion of the rack body; and
a sliding rail, wherein the assembling frame is configured to be located between the at least one assembling portion and the sliding rail, the sliding rail comprises a rail component and a slider, the rail component is disposed on the assembling frame, the slider is slidably disposed on the rail component, and the slider is configured for the at least one server to be detachably disposed thereon.

7. The sliding rail assembly according to claim 6, wherein the slider comprises at least one first positioning structure, the at least one first positioning structure comprises a wide portion and a narrow portion, the wide portion is connected to the narrow portion, a width of the wide portion is greater than a width of the narrow portion, the at least one first positioning structure is configured for at least one second positioning structure of the at least one server to be slidably disposed therein and located at the wide portion or the narrow portion, the at least one server is configured to be released from the sliding rail when the at least one second positioning structure is disposed at the wide portion, and the at least one server is configured to be held in position on the sliding rail when the at least one second positioning structure is disposed at the narrow portion.

8. The sliding rail assembly according to claim 6, wherein the assembling frame comprises at least one first engaging structure, the at least one assembling portion of the rack body comprises at least one second engaging structure, and the assembling frame is configured to be held in position on the rack body via the at least one first engaging structure engaged with the at least one second engaging structure.

9. The sliding rail assembly according to claim 6, wherein the at least one sliding rail assembly further comprises at least one flexible component, the at least one flexible component is disposed on the assembling frame, the at least one flexible component comprises at least one first blocking structure, the at least one assembling portion of the rack body comprises at least one second blocking structure, and the assembling frame is configured to be held in position on the rack body via the at least one first blocking structure blocking the at least one second blocking structure.

10. The sliding rail assembly according to claim 6, wherein the rail component is riveted to the assembling frame.
